(19) United States
(12) Patent Application Publication
(10) Pub. No.: US 2013/0248996 A1
(43) Pub. Date: Sep. 26, 2013

(54) SEMICONDUCTOR DEVICE HAVING TRANSISTOR AND DIODE

(71) Applicant: KABUSHIKI KAISHA TOSHIBA, Tokyo (JP)

(72) Inventors: Masaaki OGASAWARA, Hyogo-ken (JP); Ryuta ARAI, Hyogo-ken (JP); Shigehiro HOSOI, Hyogo-ken (JP)

(73) Assignee: KABUSHIKI KAISHA TOSHIBA, Tokyo (JP)

(21) Appl. No.: 13/780,419

(22) Filed: Feb. 28, 2013

(30) Foreign Application Priority Data
Mar. 26, 2012 (JP) 2012-068628

(51) Int. Cl. H01L 27/04

(52) U.S. Cl. CPC H01L 27/04
USPC 257/334

(57) ABSTRACT

According to one embodiment, in a semiconductor device, a first semiconductor layer of a first conductivity type is formed on a semiconductor substrate of the first conductivity type. A second semiconductor layer of a second conductivity type is formed on the first semiconductor layer at a central portion except an end portion of the semiconductor substrate. A plurality of belt-shaped control electrodes is formed in parallel through a first insulating film on a surface of the second semiconductor layer. A third semiconductor layer of the first conductivity type selectively is formed on a surface of the second semiconductor layer between the control electrodes. A first electrode is formed on the control electrodes through respective second insulating films and is in contact with the third semiconductor layer. A second electrode is formed on the first semiconductor layer at the end portion of the semiconductor substrate.

### CROSS REFERENCE TO RELATED APPLICATION

This application is based upon and claims the benefit of priority from the prior Japanese Patent Application No. 2012-068628, filed on Mar. 26, 2012, the entire contents of which are incorporated herein by reference.

### FIELD

Embodiments described herein relate generally to a semiconductor device.

### BACKGROUND

Rated voltages of batteries for portable telephones which are generally used today are about 3.8 V, and rated supply voltages of charge circuits for the batteries are 5V. Therefore, when a power source is directly connected to the battery to charge the battery, an over voltage is applied to the battery to cause a fault of the battery. Accordingly, a resistor is inserted between the power source and the battery through a MOSFET for switching, and after being reduced from 5 V to 3.8 V, the voltage is supplied.

However, in case where only the resistor is provided, there is a problem that when the voltage applied to the battery becomes not more than the rated voltage of the battery due to noise and the like, current counterflows from the battery to the power source side. For the reason, as the measure of preventing the current from counterflowing, a Schottky barrier diode (SBD) is connected in series with a drain electrode or a source electrode of the MOSFET for switching.

In the charge circuit of the portable telephone as described above, in case where the MOSFET for switching and the SBD for counterflow prevention are mounted one by one in a package (PKG), the PKG increases in size. As a result, there are problems that the design leeway of the charge circuit is eliminated and increase in cost is caused.

### BRIEF DESCRIPTION OF THE DRAWINGS

FIG. 1 is a circuit diagram showing a charge circuit of a portable telephone having a semiconductor device according to an embodiment;

FIG. 2 is a top view showing the semiconductor device according to the embodiment;

FIG. 3 is a cross-sectional view showing the semiconductor device taken along a chain line A-A′ of FIG. 2 according to the embodiment;

FIG. 4 is a schematic plan view showing a state of the semiconductor device mounted in a package according to the embodiment;

FIG. 5 is a plan view showing the semiconductor device according to the embodiment;

FIGS. 6A to 6C, 7A to 7C are cross-sectional views showing steps of manufacturing the semiconductor device in sequential order according to the embodiment; and

FIG. 8 is a plan view showing another semiconductor device according to the embodiment.

### DETAILED DESCRIPTION

According to one embodiment, in a semiconductor device, a first semiconductor layer of a first conductivity type is formed on a semiconductor substrate of the first conductivity type. A second semiconductor layer of a second conductivity type is formed on the first semiconductor layer at a central portion except an end portion of the semiconductor substrate. A plurality of belt-shaped control electrodes is formed in parallel through a first insulating film on a surface of the second semiconductor layer. A third semiconductor layer of the first conductivity type is selectively formed on a surface of the second semiconductor layer between the plurality of control electrodes. A first electrode is formed on the plurality of control electrodes through respective second insulating films and is in contact with the third semiconductor layer. A second electrode is formed on the first semiconductor layer at the end portion of the semiconductor substrate so as to be in contact with the first semiconductor layer.

Hereinafter, embodiments will be described with reference to the drawings. In the drawings, same reference characters denote the same or similar portions.

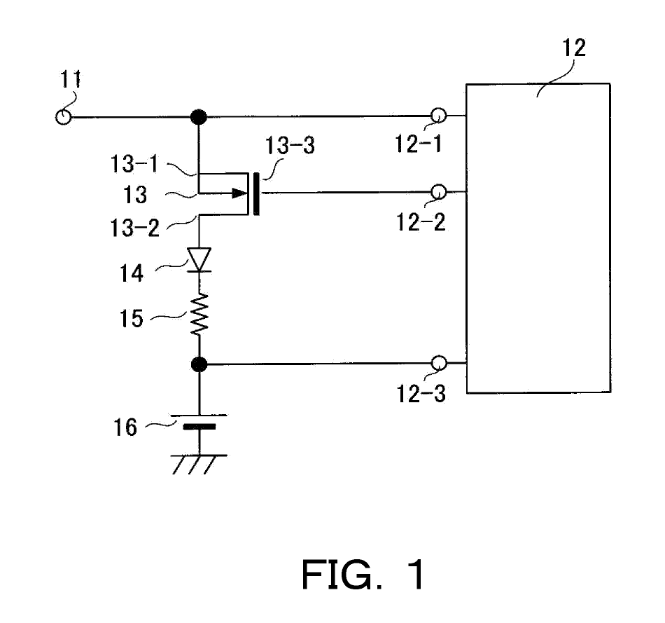

FIG. 1 shows a charge circuit of a portable telephone in which a semiconductor device of an embodiment is used. As shown in FIG. 1, a DC voltage of 5 V from an AC adapter (not shown) is supplied to an input terminal 11. The voltage is supplied to a charging voltage monitoring terminal 12-1 of a charge monitoring circuit 12, and a portion of the voltage is branched off and is supplied to a source terminal 13-1 of a field effect transistor (hereinafter, referred to as a MOSFET) 13 for switching. A Schottky barrier diode (hereinafter, referred to as an SBD) 14 is connected in series to a drain terminal 13-2 of the MOSFET 13. That is, an anode electrode side of the SBD 14 is connected to the drain terminal 13-2 of the MOSFET 13, and a cathode electrode side of the SBD 14 is connected to an anode side of a battery 16 through a resistor 15 for voltage drop. The battery 16 is a lithium ion battery with a rated voltage of 3.5 V, for example, and a cathode side of the battery 16 is earthed.

On the other hand, a gate electrode 13-3 of the MOSFET 13 is connected to a charging current control terminal 12-2 of the charge monitoring circuit 12. In addition, the anode side of the battery 16 is connected to a charging current monitoring terminal 12-3 of the charge monitoring circuit 12. The charge monitoring circuit 12 monitors a portion of a charging current supplied to the charging current monitoring terminal 12-3, and gives a control voltage of the charging current control terminal 12-2 to the gate electrode 13-3 of the MOSFET 13, and thereby controls so that the charging current to the battery 16 to be charged becomes a rated current.

The semiconductor device of the embodiment is one in which the MOSFET 13 and the SBD 14 which are series connected are integrally manufactured in a chip.

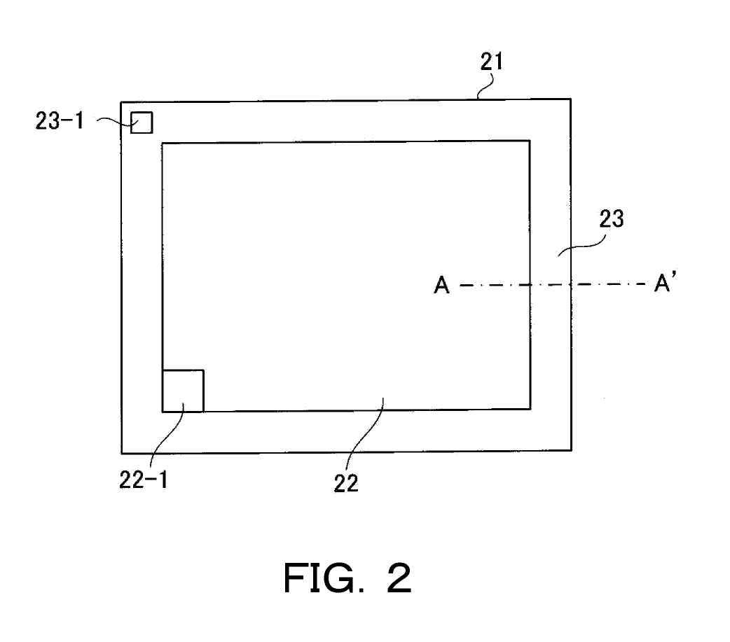

FIG. 2 is a top view of the semiconductor device of the embodiment. As can be seen from FIG. 2, the feature of the semiconductor device of the embodiment is that a MOSFET region 22 is provided at an approximately central portion of a quadrangular semiconductor chip 21, an SBD region 23 is provided around the MOSFET region 22, and thereby the MOSFET 13 and the SBD 14 shown in FIG. 1 are present within a chip. A gate pad 22-1 connected to the gate electrode 13-3 of the MOSFET 13 is disposed at a corner portion of the MOSFET region 22, and a cathode electrode 23-1 of the SBD 14 is disposed at a corner portion of the SBD region 23.

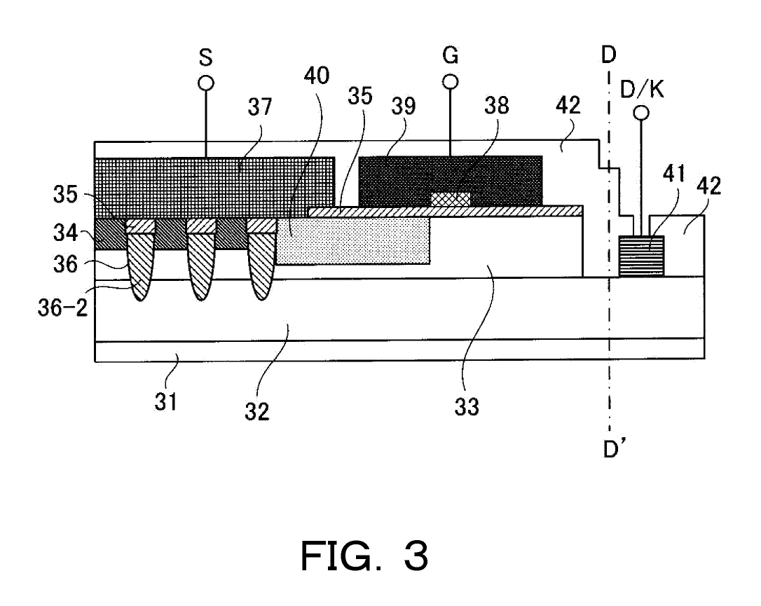

FIG. 3 is a sectional view of the semiconductor device taken along a chain line A-A′ of FIG. 2. That is, FIG. 3 shows a cross section of the peripheral portion of the semiconductor chip 21 including a portion of the MOSFET region 22 and the SBD region 23 of FIG. 2. In the drawing, the left side of a chain line D-D′ is the MOSFET region 22 shown in FIG. 2, and the right side is the SBD region 23. These regions are formed on a common P-type (a first conductivity type) Si semiconductor substrate 31. A P-type Si epitaxial layer (a first semiconductor layer) 32 of low concentration is formed on the P-type Si semiconductor substrate 31, and furthermore an N-type (a second conductivity type) base layer (a second semiconductor layer) 33 is formed on the P-type Si epitaxial layer 32. The Si epitaxial layer 32 forms a P-type drain layer of the MOSFET 13.

The MOSFET 13 (FIG. 1) within the MOSFET region 22 is formed of a P-type source layer (a third semiconductor layer) 34 formed on the surface portion of the N-type base layer 33, a plurality of trench gates (control electrodes) 36 which penetrate through the N-type base layer 33 and reach the P-type epitaxial layer 32 in the region of the P-type source layer 34, and the P-type Si semiconductor substrate 31. Here, a source electrode (a first electrode) 37 of the MOSFET 13 is formed of metal material such as aluminum to perform ohmic contact with the P-type source layer 34 on the surface of the P-type source layer 34, and a source electrode terminal S is derived from the source electrode 37. In addition, within each of the multiple trench gates 36, a polysilicon layer 36-2 to form a gate electrode to which N-type impurities are ion-implanted is buried through a gate insulating film (a first insulating film) (not shown). The surface of the polysilicon layer 36-2 is insulated from the source electrode 37 by an insulating layer (a second insulating film) 35. The polysilicon layers 36-2 within the multiple trench gates 36 are collectively connected to a polysilicon wiring 38 which is provided on the surface of the N-type base layer 33 through the insulating layers 35, as described later. A gate electrode wiring 39 having the laminated structure of titanium tungsten (TiW) and aluminum (Al) is formed on the polysilicon wiring 38 so as to cover the polysilicon wiring 38, and a gate electrode terminal G is derived from the gate electrode wiring 39. A drain electrode terminal D which is common to a cathode electrode of the SBD 14 is derived from the P-type epitaxial layer 32 to form the drain layer, as described later. In addition, an N-type carrier extracting layer 40 to be described later is selectively formed on the surface of the N-type base layer 33.

On the other hand, in the SBD region 23, the SBD 14 (FIG. 1) which is a Schottky barrier diode in which a cathode electrode (a second electrode) 41 having the laminated structure of titanium tungsten (TiW) and aluminum (Al) in the same manner as the above-described gate electrode wiring 39 is directly bonded on the surface of the P-type Si epitaxial layer 32 is formed. A cathode electrode terminal K of the SBD 14 is derived from the cathode electrode 41 of the SBD 14. In addition, an anode layer of the SBD 14 is the P-type epitaxial layer 32 which is common to the drain layer of the MOSFET 13. Accordingly, the drain electrode terminal D of the MOSFET 13 is not directly drawn outside, but is drawn out as a common terminal to the cathode electrode K through the cathode electrode 41 of the SBD 14. In addition, a protective film 42 such as a nitride film is formed on the entire surface of the device including the MOSFET 13 and the SBD 14.

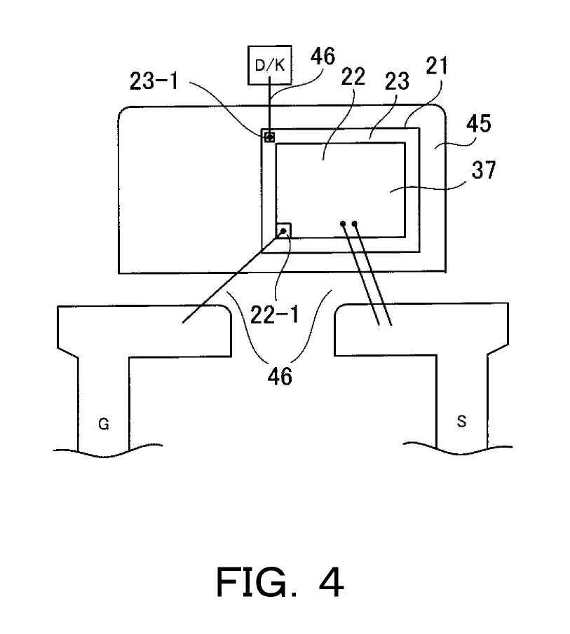

FIG. 4 is a schematic top view showing the state in which the semiconductor device of the embodiment configured as described above is mounted in a package for a charge circuit of a portable telephone. The semiconductor chip 21 is mounted in a package main body 45, and the cathode pad 23-1, the source electrode 37 and the gate pad 22-1 are respectively connected through bonding wires 46 to the electrode terminals D/K, S, G which are provided around the package main body 45.

In the semiconductor device of the embodiment, the MOSFET 13 is formed at the approximately central portion of the same P-type Si semiconductor substrate 31, and the SBD 14 is formed around the MOSFET 13. The P-type Si epitaxial layer 32 of low concentration that is the drain layer of the MOSFET 13 simultaneously functions as the anode layer of the SBD 14. In case where a control voltage to make the MOSFET 13 in the ON state is applied to the gate electrode wiring 39, a charging current supplied from the external input terminal 11 (FIG. 1) to the source electrode 37 passes through the source layer 34 between the trench gates 36 and enters the base layer 33. The current passes through the drain layer 32 under the base layer 33, enters within the P-type semiconductor substrate 31 of high concentration, moves within the semiconductor substrate 31 in the direction of the end portion where the SBD 14 is provided, and returns again to the drain layer 32 which doubles as the anode layer of the SBD 14. Finally, the current is taken out at the cathode terminal K through the cathode electrode 41 of the SBD 14. The charging current is supplied to the battery 16 through the resistor 15 for voltage drop as shown in FIG. 1. When the voltage applied to the battery becomes not more than the rated voltage due to noise and the like during charging, the current might counterflow to the external input terminal 11 side from the battery. But, in the above-described semiconductor device 21, the current which tries to counterflow in the above-described current pathway is blocked by the generation of a reverse bias voltage between the cathode electrode 41 and the anode layer 32 of the SBD 14.

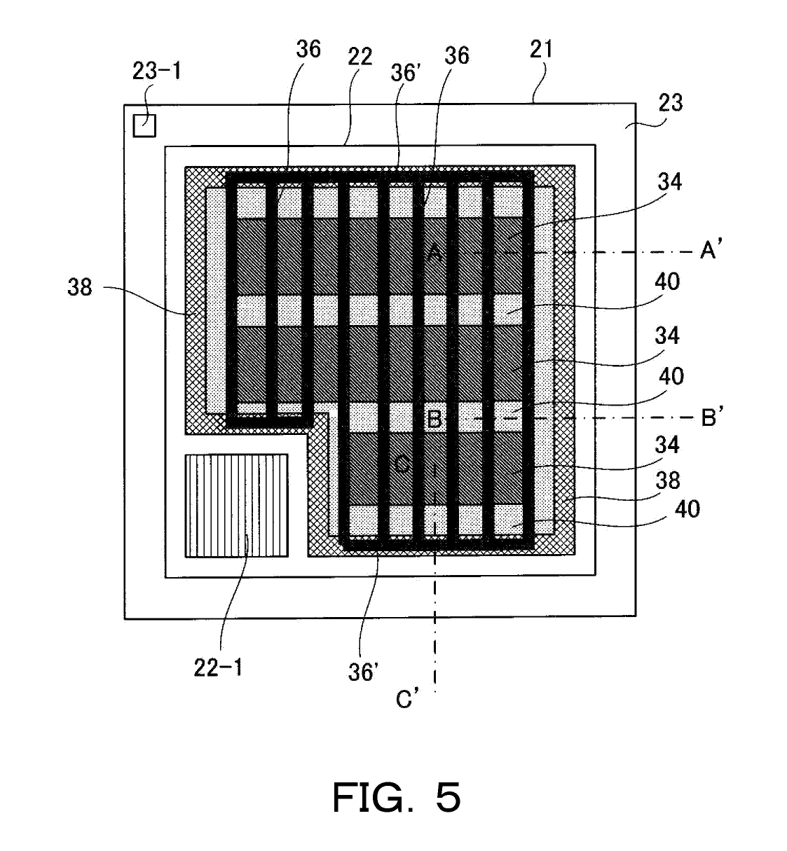

Next, an outline of a manufacturing method of the semiconductor device of the embodiment will be described with reference to FIG. 5 to FIG. 7C.

To begin with, FIG. 5 is a top view showing the structure of the semiconductor device in a midway stage of the manufacturing process of the semiconductor device of the embodiment. That is, FIG. 5 is the top view of the semiconductor device corresponding to FIG. 2, and is the view showing the pattern of the surface portion of the N-type base layer 33 which is exposed by removing the surface protective film 42 (FIG. 3), the source electrode 37 and the gate electrode wiring 39 in FIG. 2.

As shown in FIG. 5, the MOSFET region 22 is provided at the approximately central portion of the semiconductor chip 21, and the SBD region 23 is provided around the MOSFET region 22. The multiple elongated trench gates 36 which extend in the longitudinal direction and in parallel are arranged in the MOSFET region 22. Elongated trench gates 36′ extending in the crosswise direction are formed at the upper and lower end portions of the trench gates 36 arranged in the longitudinal direction, and the polysilicon layers which are buried inside the trench gates 36, 36′ are mutually connected. The trench gates 36′ extending in the crosswise direction are connected to the polysilicon wiring 38 which is wired around the MOSFET region 22. Though not shown, the surface of the polysilicon wiring 38 is coated over the whole length with the gate electrode wiring 39 (FIG. 3). The polysilicon wiring 38 coated with the gate electrode wiring 39 is connected to the gate pad 22-1 provided at the corner portion of the semiconductor chip 21.

The multiple P-type source layers 34 which extend in the crosswise direction and in belt shape are also formed in the MOSFET region 22 and the trench gates 36 extending in the longitudinal direction are arranged across the P-type source layers 34. The N-type carrier extracting layers 40 are formed in the MOSFET region 22 except the region in which the P-type source layers 34 are formed. N-type impurities of the concentration higher than that of the N-type base layer 33 are doped in the N-type carrier extracting layer 40. By providing the N-type carrier extracting layers 40, out of carrier pairs of an electron and a hole which are generated by the electric field concentration in the vicinity of the lower end portion of the trench gate 36 in the state in which the MOSFET 13 is OFF, electrons are absorbed into the source electrode side through the N-type carrier extracting layer 40. Therefore, the improvement of withstanding voltage and the improvement of avalanche resistance can be achieved.

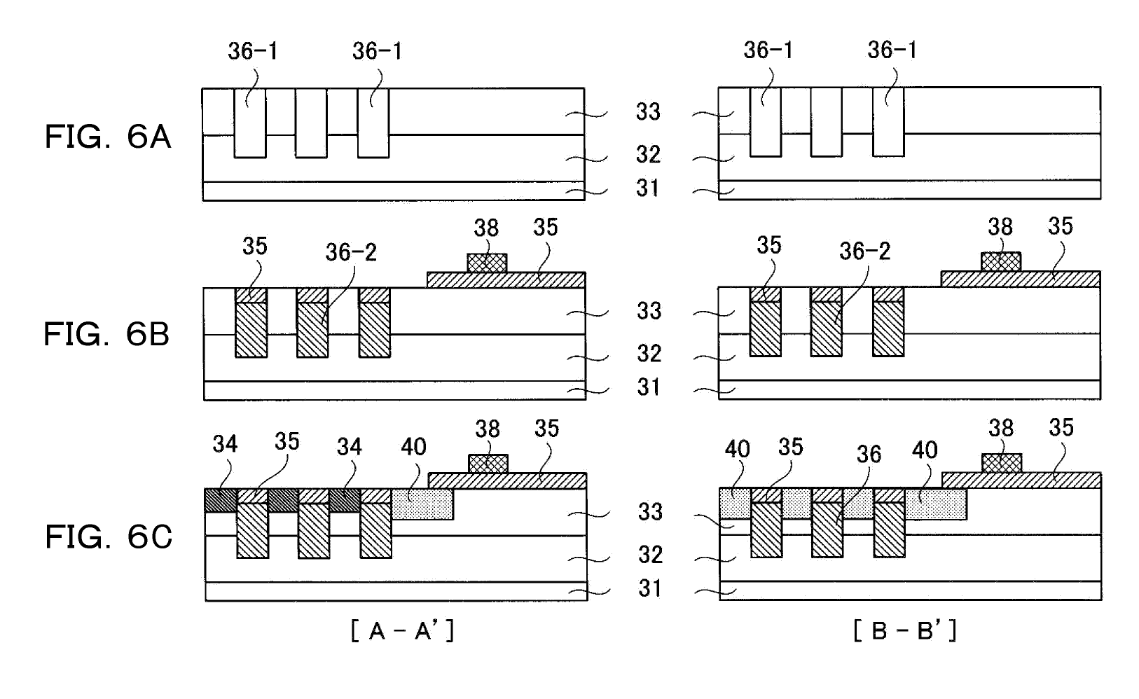

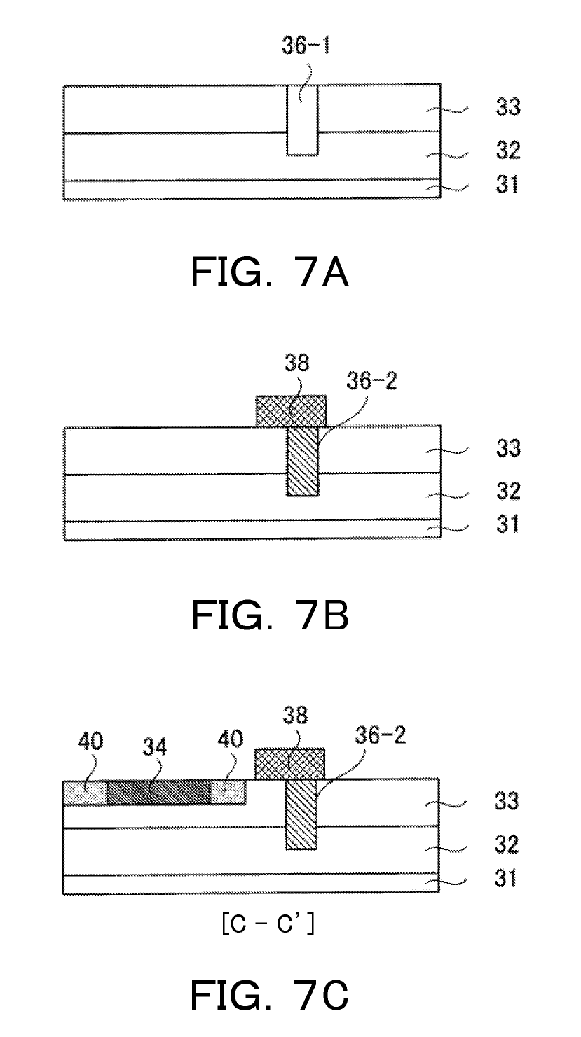

FIGS. 6A to 6C are process diagrams each showing a process of manufacturing the semiconductor device of the embodiment using sectional views along chain lines A-A′ and B-B′ in FIG. 5. In addition, FIGS. 7A to 7C are process diagrams each showing a process of manufacturing the semiconductor device of the embodiment using a sectional view along a chain line C-C′ in FIG. 5.

As shown in FIG. 6A and FIG. 7A, the P-type epitaxial layer 32 is formed on the P-type silicon semiconductor substrate 31 with the high concentration by an epitaxial growth method. Phosphorus (P) ions that are N-type impurities are implanted into the P-type epitaxial layer 32 from the surface by an ion implantation method, and the low concentration N-type base layer 33 is formed by thermal oxidation. Then, a protective film (not shown) with a moderate thickness is formed by a CVD process, and heat treatment is applied to the protective film.

Next, resist (not shown) is applied to the protective film, and multiple resist patterns which extend linearly and in parallel are formed on a plane surface of the semiconductor substrate by photolithography. Subsequently, the protective film is removed by dry etching using the resist patterns as a mask, so that patterning of the protective films which extend linearly and in parallel in the direction of the plane surface of the semiconductor substrate is performed.

After the resist patterns are removed by ashing, trenches 36-1 each having a depth enough to penetrate through the base layer 33 from the upper surface of the low concentration N-type base layer 33 and reach the P-type epitaxial layer 32, and a desired width are formed, by dry etching using the patterned protective film as a mask. The multiple trenches 36-1 formed at this time extend linearly and in parallel in the plane surface of the semiconductor substrate, as shown in FIG. 5.

In order to reduce a damage of an inner wall of the trench 36-1, a sacrificial oxide film (not shown) is formed by thermal oxidation, and the sacrificial oxide film is removed by wet etching. Subsequently, silicon of the inner wall of the trench 36-1 is oxidized by a thermal oxidation method, so that a desired gate insulating film (not shown) is formed. After a polysilicon film which forms a gate electrode is deposited, P ions that are N-type impurities are implanted into the polysilicon film by an ion implantation method. The polysilicon film is etched using a patterned resist (not shown) as a mask, and thereby the polysilicon layer 36-2 is formed within the trench 36-1 and the polysilicon wiring 38 is formed on the surface of the base layer 33, as shown in FIG. 6B and FIG. 7B.

An interlayer insulating film with a proper thickness is formed by a CVD process, and the interlayer insulating film is etched back, and thereby the insulating film 35 with a desired film thickness is formed on the gate electrode 36-2 within the trench 36-1, as shown in FIG. 6B and FIG. 7B. Next, as shown in FIG. 6C and FIG. 7C, P ions that are N-type impurities are implanted with an ion implantation method, using a patterned resist (not shown) as a mask, and thereby the belt-shaped high concentration N-type carrier extracting layers 40 are formed at the positions shown in FIG. 5. Then, B ions that are P-type impurities are implanted by an ion implantation method, using patterning of resist, and thereby the belt-shaped P-type source layers 34 are formed at the positions shown in FIG. 5. And the impurity ions are activated by annealing.

Using a patterned resist (not shown) as a mask, etching is performed so that the oxide film at the end portion is removed and the N-type epitaxial layer 32 is exposed to the surface by wet etching. Using a patterned resist (not shown) as a mask, as shown in FIG. 3, the source electrode 37 is formed on the P-type source layer 34 and the high concentration N-type carrier extracting layer 40, the gate electrode wiring 39 is formed on the gate polysilicon wiring 38, and the cathode electrode 41 is formed on the N-type epitaxial layer 32 which has been exposed to the surface by wet etching at the end portion. By this means, the source electrode and gate electrode wiring 39 are formed within the MOSFET region 22, and the cathode electrode 41 is formed within the SBD region 23. Then, the protective film 42 (FIG. 3) such as the nitride film, for example, is formed on the entire surface of the device.

The semiconductor device manufactured in this manner can realize the function of the MOSFET for switching and the function of the SBD for counterflow protection by a single chip. As a result, it becomes possible that the semiconductor device is mounted in smaller equipments.

By means of the semiconductor device of the embodiment, in a charge circuit of a portable telephone, a MOSFET with a switching function and an SBD with a voltage drop and counterflow protection function can be realized by a single chip, and it becomes possible that the semiconductor device is mounted in a smaller package. As a result, miniaturization of a charge circuit and design leeway expansion of a charge circuit can be achieved.

The invention is not limited to the above-described embodiment, but various modifications are enabled. The cathode terminal K of the SBD 14 has been drawn out from the upper surface of the device, for example, but the cathode terminal K of the SBD 14 can be formed at the rear surface of the P-type Si semiconductor substrate 31, and thereby the cathode terminal K of the SBD 14 can also be drawn out from the rear surface of the device.

In addition, as the MOSFET 13, the structure has been used in which the belt-shaped P-type source layers 34 and the N-type carrier extracting layers 40 are alternately arranged in the direction to cross against the longitudinal direction of the trench gates at the surface portion of the base layer 33, but a structure may be used in which the P-type source layers 34 and the N-type carrier extracting layers 40 are alternately arranged in parallel with the trench gates 36.

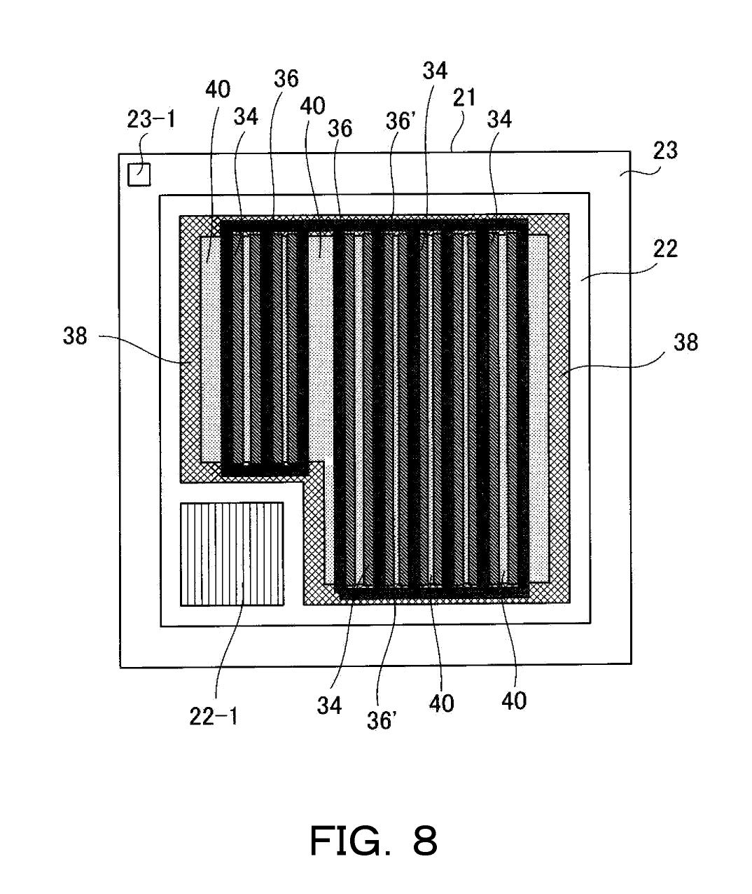

FIG. 8 is a plan view showing the structure of a semiconductor device of a modification. FIG. 8 shows the structure of the device at a midway stage in the manufacturing process. FIG. 8 corresponds to the plan view shown in FIG. 5. As the P-type source layers 34, the P-type source layers 34 of a thin belt shape are formed at the both sides of the trench gate 36 arranged to extend in the longitudinal direction. The N-type carrier extracting layer 40 is formed at a region between the P-type source layers 34 between a pair of the adjacent trench gates 36.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor substrate of a first conductivity type;
a first semiconductor layer of the first conductivity type formed on the semiconductor substrate;
a second semiconductor layer of a second conductivity type formed on the first semiconductor layer at a central portion except an end portion of the semiconductor substrate;
a plurality of belt-shaped control electrodes formed in parallel through a first insulating film on a surface of the second semiconductor layer;
a third semiconductor layer of the first conductivity type selectively formed on a surface of the second semiconductor layer between the plurality of control electrodes;
a first electrode formed on the plurality of control electrodes through respective second insulating films and being in contact with the third semiconductor layer; and
a second electrode formed on the first semiconductor layer at the end portion of the semiconductor substrate so as to be in contact with the first semiconductor layer.

2. The semiconductor device according to claim 1, wherein the second electrode is continuously formed at the end portion of the semiconductor substrate so as to surround a periphery of a MOSFET region in which the first electrode, the third semiconductor layer and the control electrodes are formed.

3. The semiconductor device according to claim 2, wherein the control electrode is a trench gate having a depth enough to reach the first semiconductor layer from the surface of the second semiconductor layer.

4. The semiconductor device according to claim 3, wherein the third semiconductor layers are formed in a plurality of belt-shaped regions which are arranged to extend in a direction to cross a longitudinal direction of the belt-shaped control electrodes.

5. The semiconductor device according to claim 4, wherein a carrier extracting layer of the second conductivity type is formed at a region between a plurality of the belt-shaped third semiconductor layers.

6. The semiconductor device according to claim 5, wherein the first conductivity type is a P-type and the second conductivity type is an N-type.

7. The semiconductor device according to claim 6, wherein the second electrode is a Schottky electrode having a double-layered structure of a titanium tungsten alloy layer and an aluminum layer.

8. The semiconductor device according to claim 7, wherein the control electrodes are connected to a control electrode wiring which is continuously formed at the end portion of the MOSFET region so as to surround a periphery of a region in which the third semiconductor layers and the control electrodes are formed.

9. The semiconductor device according to claim 8, wherein the control electrode wiring has a double-layered structure of a titanium tungsten alloy layer and an aluminum layer.

10. A semiconductor device, comprising:
a semiconductor substrate of a first conductivity type;
a drain layer of the first conductivity type formed on the semiconductor substrate;
a base layer of a second conductivity type formed on the drain layer at a central portion except an end portion of the semiconductor substrate;
a plurality of belt-shaped trench gates formed in parallel and having a depth enough to reach the drain layer from the surface of the base layer.
a source layer of the first conductivity type selectively formed on a surface of the base layer between the plurality of trench gates;
a source electrode formed on the plurality of trench gates through respective insulating films and being in contact with the source layer;
a gate electrode wiring connected to the plurality of trench gates; and
a Schottky electrode formed on the drain layer exposed at the end portion of the semiconductor substrate.

11. The semiconductor device according to claim 10, wherein the Schottky electrode is continuously formed at the end portion of the semiconductor substrate so as to surround a periphery of a MOSFET region in which the source electrode, the source layer and the trench gates are formed.

12. The semiconductor device according to claim 10, wherein the source layers are formed in a plurality of belt-shaped regions which are arranged to extend in a direction to cross a longitudinal direction of the belt-shaped trench gates.

13. The semiconductor device according to claim 4, wherein a carrier extracting layer of the second conductivity type is formed at a region between a plurality of the belt-shaped source layers.

14. The semiconductor device according to claim 10, wherein the first conductivity type is a P-type and the second conductivity type is an N-type.

15. The semiconductor device according to claim 10, wherein the Schottky electrode is a double-layered structure of a titanium tungsten alloy layer and an aluminum layer.

16. The semiconductor device according to claim 10, wherein the trench gates are connected to a gate electrode wiring which is continuously formed at the end portion of the MOSFET region so as to surround a periphery of a region in which the source layers and the trench gates are formed.

17. The semiconductor device according to claim 10, wherein the gate electrode wiring has a double-layered structure of a titanium tungsten alloy layer and an aluminum layer.
